(19) United States
(12) Patent Application Publication
(10) Pub. No.: US 2008/0062662 A1
(43) Pub. Date: Mar. 13, 2008

(54) Electronic apparatus and method of making the same

(75) Inventors: Takashi Iijima, Kawasaki (JP); Sonomasa Kabayashi, Kawasaki (JP); Kaigo Tanaka, Kawasaki (JP)

Correspondence Address: STAAS & HALSEY LLP, SUITE 700, 1201 NEW YORK AVENUE, N.W., WASHINGTON, DC, 20005, US

(73) Assignee: FUJITSU LIMITED, Kawasaki (JP)

(21) Appl. No.: 11/703,240

(22) Filed: Feb. 7, 2007

(30) Foreign Application Priority Data
Sep. 12, 2006 (JP) 2006-247360

(51) Int. Cl. H05K 5/00

(52) U.S. Cl. 361/752; 29/592.1

(57) ABSTRACT

A cover is coupled to a base with the inner surface of the cover opposed to the inner surface of the base. In this case, a rib standing from the inner surface of the cover is guided along the contour of a printed wiring board fixed to the inner surface of the base. The method allows the printed wiring board on the base to guide the movement of the rib of the cover. The printed wiring board is utilized to align the cover with the base with a higher accuracy. The cover is thus reliably prevented from colliding against an electronic component mounted on the printed wiring board. This results in a reliable avoidance of damage to the electronic component.

### BACKGROUND OF THE INVENTION

1. Field of the Invention

The present invention relates to an electronic apparatus including a printed wiring board and the like placed in an inner space defined between a base and a cover. In particular, the present invention relates to a method of making an electronic apparatus comprising coupling a cover to a base with the inner surface of the cover opposed to the inner surface of the base.

2. Description of the Prior Art

A notebook personal computer including a fingerprint sensor is well known. A fingerprint sensor module is incorporated in the enclosure of the notebook personal computer to establish the fingerprint sensor. The fingerprint sensor module is mounted on a printed wiring board. The printed wiring board is fixed on the base of the enclosure.

A cover is coupled to the base to establish the enclosure. The printed wiring board is covered with the cover. An opening is formed in the cover at a position corresponding to the position of the fingerprint sensor module on the printed wiring board. The fingerprint sensor module is located in the opening. The user of the notebook personal computer can slide a finger on the fingerprint sensor module along the outer surface of the enclosure.

The cover is coupled with the base to establish the enclosure. The contour of the cover is aligned with the contour of the base. The worker cannot see the fingerprint sensor module because the cover completely hides the fingerprint sensor module on the base. The edge of the opening is often caused to collide against the fingerprint sensor module. This results in a serious damage to the fingerprint sensor module.

### SUMMARY OF THE INVENTION

It is accordingly an object of the present invention to provide a method of making an electronic apparatus, capable of a reliable avoidance of damage to an electronic component on a printed wiring board during the assembling of the enclosure of the electronic apparatus. It is also an object of the present invention to provide the structure of an electronic apparatus significantly contributing to realization of the method.

According to a first aspect of the present invention, there is provided a method of making an electronic apparatus, comprising coupling a cover to a base with the inner surface of the cover opposed to the inner surface of the base while a rib standing from the inner surface of the cover is guided along the contour of a printed wiring board fixed to the inner surface of the base

The method allows the printed wiring board on the base to guide the movement of the rib of the cover. The printed wiring board is utilized to align the cover with the base with a higher accuracy. The cover is thus reliably prevented from colliding against an electronic component mounted on the printed wiring board, for example. This results in a reliable avoidance of damage to the electronic component.

The rib may define an inclined surface getting farther from an imaginary surface surrounding the printed wiring board in an attitude perpendicular to the printed wiring board at a position farther from the inner surface of the cover. The inclined surface gets farther from the imaginary surface at a position farther from the inner surface of the cover. Even if the cover is slightly shifted from the target position relative to the base, the inclined surface of the rib is allowed to slide along the contour of the printed wiring board. This results in a smooth assembling.

An opening may be formed in the cover at a position corresponding to the position of the electronic component mounted on the printed wiring board in the method. The cover can be aligned with the base with a higher accuracy as described above. The edge of the opening can reliably be prevented from colliding with the electronic component on the printed wiring board. This results in a reliable avoidance of damage to the electronic component.

A fingerprint sensor may be employed as the electronic component. The fingerprint sensor can easily be damaged from collision. Accordingly, the method according to the present invention is much useful when the fingerprint sensor is mounted on the printed wiring board.

According to a second aspect of the present invention, there is provided an electronic apparatus comprising: a base; a cover coupled with the base; a printed wiring board fixed on the base; and a rib standing upright from the inner surface of the cover toward the base, the rib defining a contact surface along an imaginary surface surrounding the contour of the printed wiring board in an attitude perpendicular to the printed wiring board. The electronic apparatus of this type significantly contributes to realization of the aforementioned method.

The rib may define an inclined surface getting farther from the imaginary surface at a position farther from the inner surface of the cover in the electronic apparatus. An opening may be formed in the cover at a position corresponding to the position of an electronic component mounted on the printed wiring board in the same manner as described above. The electronic component may be a fingerprint sensor.

### BRIEF DESCRIPTION OF THE DRAWINGS

The above and other objects, features and advantages of the present invention will become apparent from the following description of the preferred embodiment in conjunction with the accompanying drawings, wherein:

FIG. 1 is a perspective view schematically illustrating a notebook personal computer as a specific example of an electronic apparatus according to the present invention;

FIG. 2 is an enlarged partial perspective view schematically illustrating the surface of a display enclosure;

FIG. 3 is an exploded view schematically illustrating the display enclosure;

FIG. 4 is a perspective view schematically illustrating a cover;

FIG. 5 is a sectional view of the display enclosure for schematically illustrating engagement between claws;

FIG. 6 is a partial exploded view schematically illustrating wires extending from a printed wiring board;

FIG. 7 is a plan view schematically illustrating the relative positions of the printed wiring board and ribs;

FIG. 8 is a sectional view taken along the line 8-8 in FIG. 7;

FIG. 9 is a sectional view schematically illustrating the alignment of the contour of the cover with the contour of the base prior to engagement of the claws; and

FIG. 10 is an enlarged partial perspective view schematically illustrating the ribs aligned with the printed wiring board.

### DESCRIPTION OF THE PREFERRED EMBODIMENT

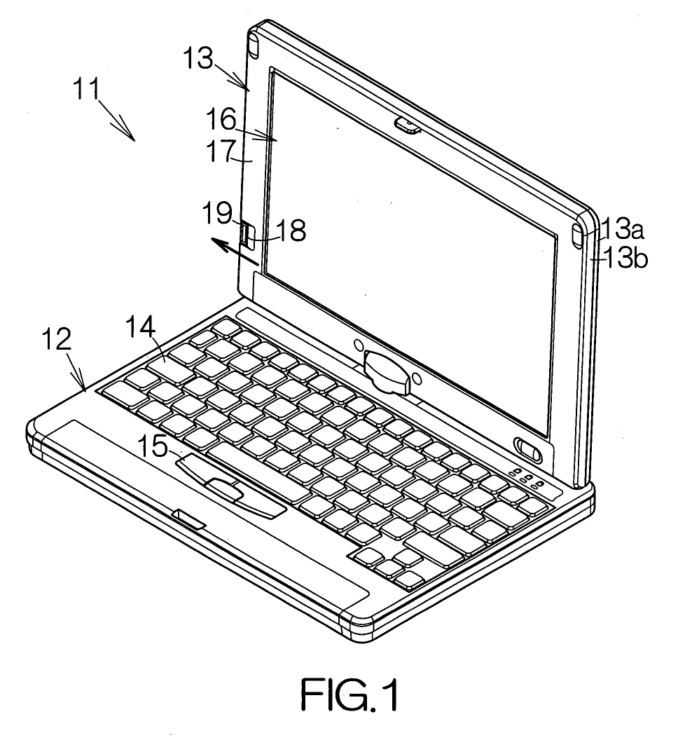

FIG. 1 schematically illustrates a notebook personal computer 11 as a specific example of an electronic apparatus according to the present invention. The notebook personal computer 11 includes a thin first enclosure, namely a main body enclosure 12, and a second enclosure, namely a display enclosure 13. The display enclosure 13 is coupled to the main body enclosure 12 for a relative swinging movement. Input devices such as a keyboard 14 and a pointing device 15 are embedded in the surface of the main body enclosure 12. Users manipulate the keyboard 14 and/or the pointing device 15 to input commands and/or data.

The display enclosure 13 includes a base 13a and a cover 13b removably coupled with the base 13a. A liquid crystal display (LCD) panel module 16 is enclosed in the display enclosure 13, for example. A frame 17 of the cover 13b surrounds the screen of the LCD panel module 16. Texts and graphics are displayed on the screen. Users can see the ongoing operation of the notebook personal computer 11 based on the displayed texts and graphics. The display enclosure 13 can be superimposed on the main body enclosure 12 through the pivotal movement relative to the main body enclosure 12.

An electronic component, namely a fingerprint sensor module 19 is located in an opening 18 formed in the frame 17. The fingerprint sensor module 19 is located inside the contour of the display enclosure 13 or frame 17. The fingerprint sensor module 19 is designed to scan the fingerprint of a finger moving in a direction outward from the screen. The finger may move along the surface of the frame 17, for example. An image of the scanned fingerprint may temporarily be stored in a memory on a motherboard enclosed in the main body enclosure 12, for example.

The fingerprint sensor module 19 is utilized for authentication at log-on to an operating system (OS) or a network, the startup of a software program, or the like. Users first register fingerprint data including images of the fingerprints of their right/left hands in the notebook personal computer 11. The registered fingerprint data is stored in a hard disk drive, HDD, enclosed in the main body enclosure 12, for example. A central processing unit (CPU) on the motherboard compares a fingerprint data of a scanned fingerprint with the registered fingerprint data based on a software program for authentication of a fingerprint stored in the hard disk drive, for example. Authentication of a fingerprint is realized in this manner.

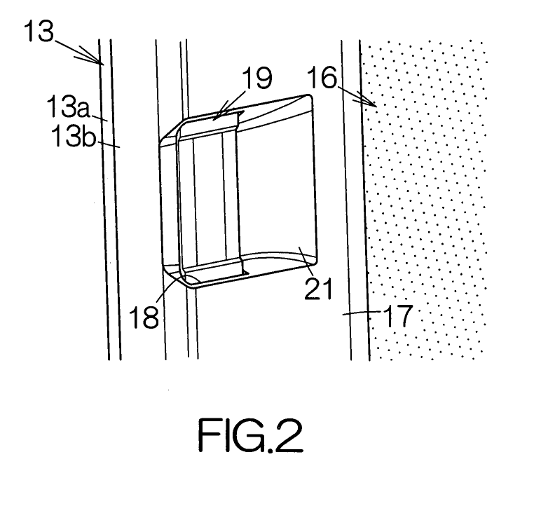

As shown in FIG. 2, a depression 21 is formed in the frame 17 of the cover 13b. The fingerprint sensor module 19 is located in the opening 18 in the depression 21. A predetermined gap is defined between the fingerprint sensor module 19 and the edge of the opening 18. The gap serves to prevent the edge of the opening 18 from contacting with the fingerprint sensor module 19. The fingerprint sensor module 19 includes a line sensor having linear pixels in the longitudinal direction of the fingerprint sensor module 19. A semiconductor sensor utilizing an electric field or electric capacitance is employed as the line sensor, for example.

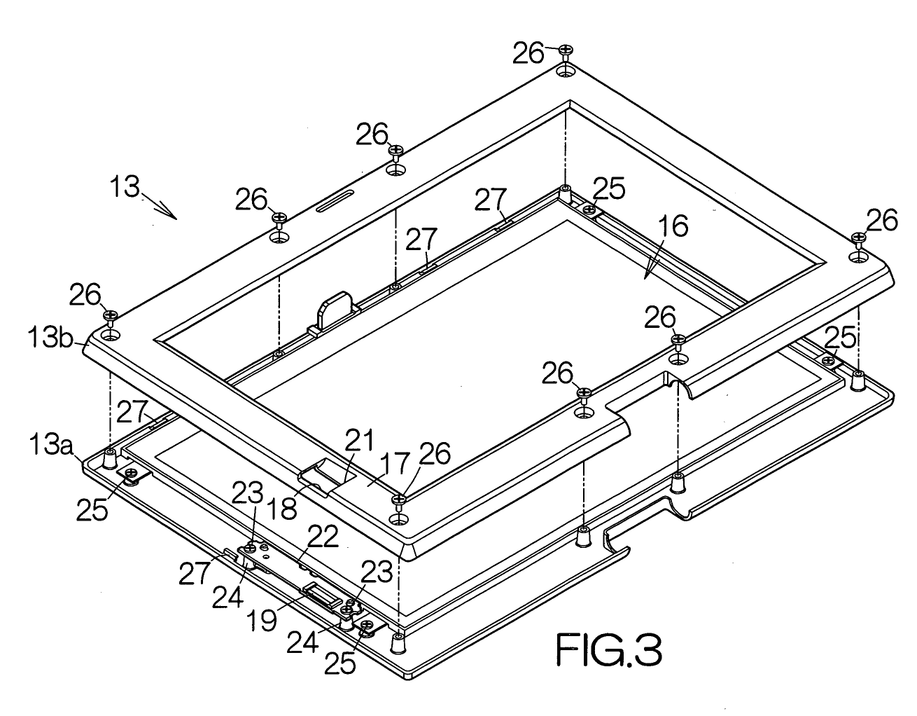

As shown in FIG. 3, the fingerprint sensor module 19 is mounted on a printed wiring board 22. The printed wiring board 22 is fixed to the base 13a at a position outside the LCD panel module 16. A screw 23 is utilized to fix the printed wiring board 22, for example. The screw 23 may be received in a boss 24 standing upright from the inner surface of the base 13a. The opening 18 of the cover 13b is formed at a position corresponding to the position of the fingerprint sensor module 19. A screw 25 is utilized to fix the LCD panel module 16 to the base 13a.

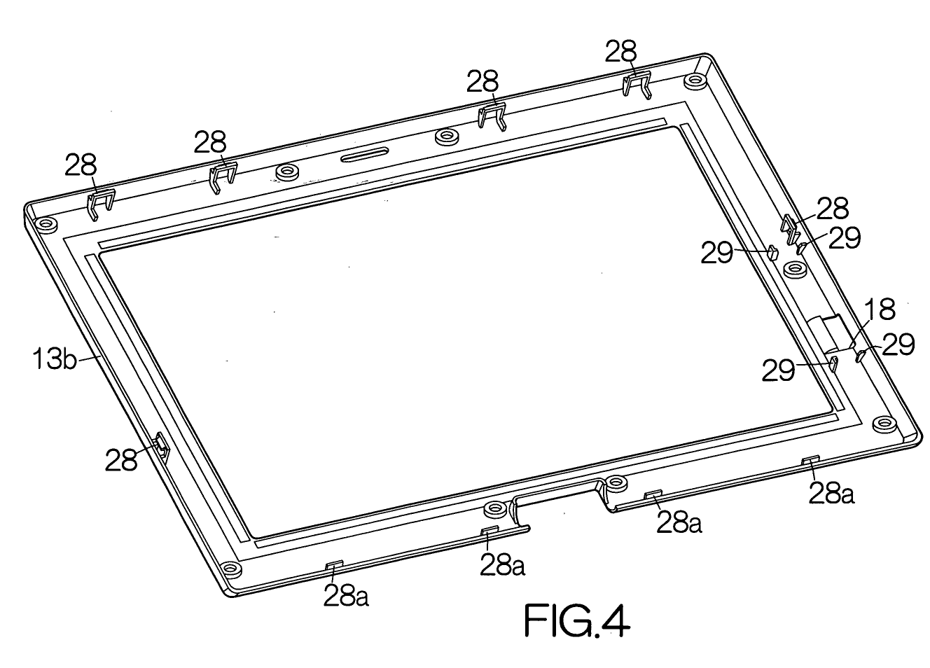

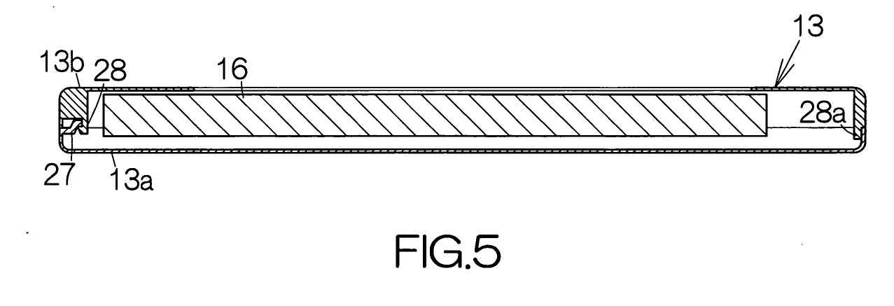

A screw 26 is utilized to fix the base 13a to the cover 13b. Claws 27 are formed on the surrounding wall of the base 13a. The claws 27 have hooks extending inward. The claws 27 may be formed integral with the base 13a. As shown in FIG. 4, engagement pieces 28, 28a are formed on the surrounding wall of the cover 13b. The engagement pieces 28, namely the claws, have hooks extending outward. The engagement pieces 28, 28a may be formed integral with the cover 13b. As shown in FIG. 5, the engagement pieces 28 of the cover 13b are engaged with the corresponding claws 27 of the base 13a. The base 13a and the cover 13b are coupled with each other in this manner. It should be noted that the engagement pieces 28a are simply received on the inner surface of the surrounding wall of the base 13a.

As is apparent from FIG. 4, four ribs 29 are formed on the inner surface of the cover 13b, for example. The ribs 29 stand upright from the inner surface of the frame 17. The ribs 29 may be formed integral with the cover 13b. The ribs 29 are utilized for positioning the fingerprint sensor module 19 relative to the opening 18 of the cover 13b in the process of assembling the display enclosure 13 as described later. Since the ribs 29 are formed integral with the cover 13b, the ribs 29 can be aligned with the opening 18 with a higher accuracy.

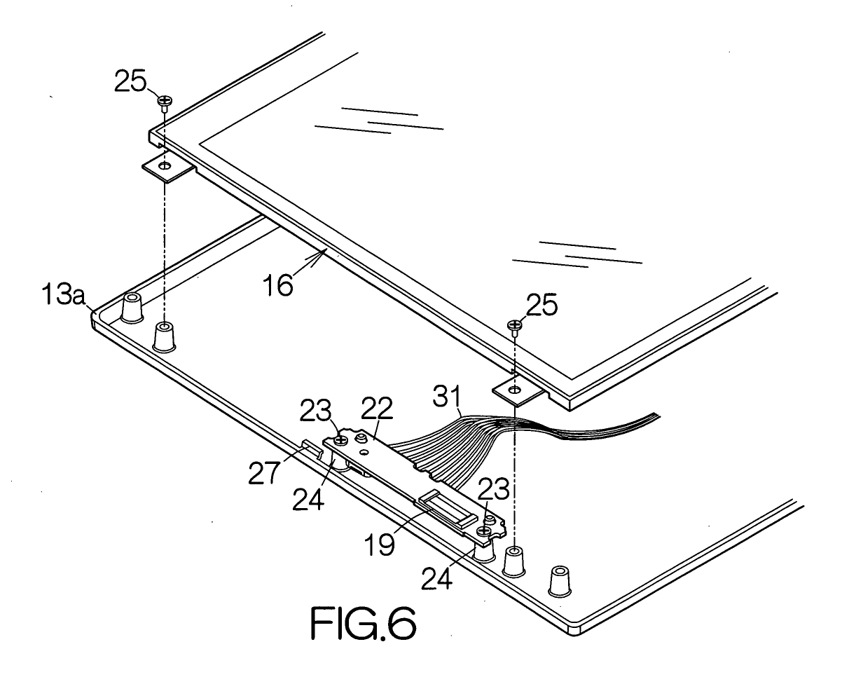

As shown in FIG. 6, one ends of wires 31 are connected to the printed wiring board 22, for example. The other ends, not shown, of the wires 31 are connected to the motherboard enclosed in the main body enclosure 12, for example. The printed wiring board 22 is supplied with electric current from the motherboard through the wires 31. The supplied electric current activates the fingerprint sensor module 19. The wires 31 may be located between the back surface of the LCD panel module 16 and the inner surface of the base 13a.

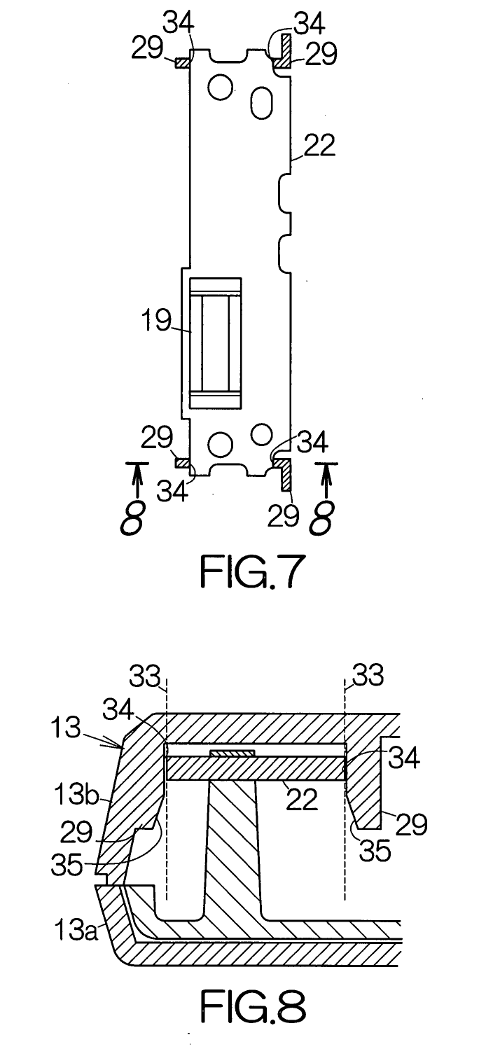

As shown in FIG. 7, the ribs 29 are located near the four corners of the printed wiring board 22. Referring also to FIG. 8, the individual rib 29 defines a contact surface 34 along an imaginary surface 33 surrounding the printed wiring board 22 in an attitude perpendicular to the printed wiring board 22. The contact surfaces 34, 34 of a pair of the ribs 29, 29 may be opposed to each other. The printed wiring board 22 is interposed between the ribs 29, 29. The individual rib 29 defines an inclined surface 35 connected to the contact surface 34. The inclined surface 35 gets farther from the imaginary surface 33 at a position getting farther from the inner surface of the frame 17.

Next, a brief description will be made on a method of assembling the display enclosure 13. The printed wiring board 22 is first attached to the base 13a. The screw 23 is screwed into the base 13a for the attachment. The fingerprint sensor module 19 is mounted on the printed wiring board 22 before the attachment. The LCD panel module 16 is subsequently attached to the base 13a. The screw 25 is screwed into the base 13a for the attachment. The wires 31 extending from the printed wiring board 22 is located between the back surface of the LCD panel module 16 and the inner surface of the base 13a.

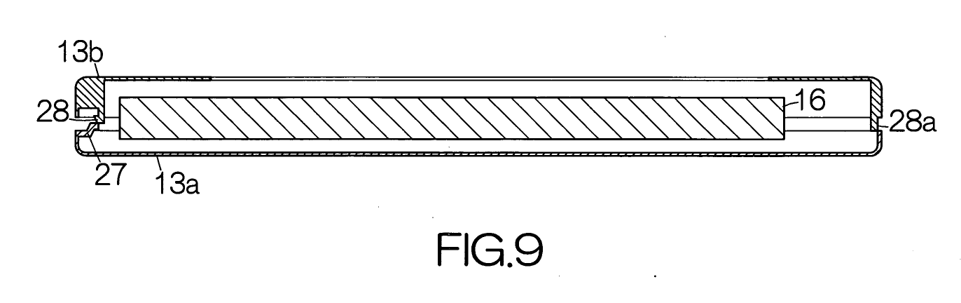

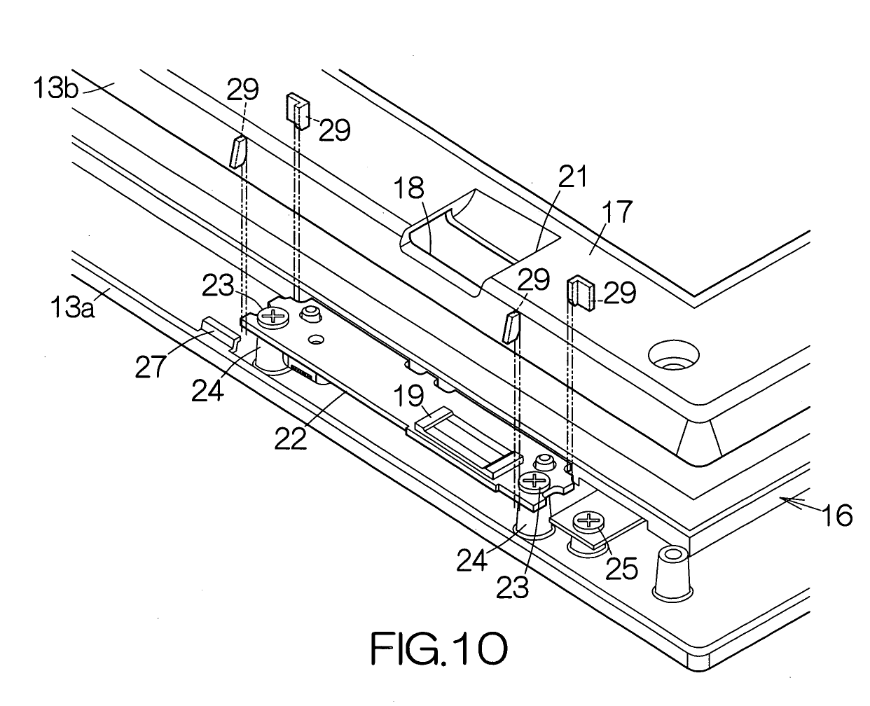

The inner surface of the cover 13b is then opposed to the inner surface of the base 13a. As shown in FIG. 9, the engagement pieces 28 of the cover 13b are roughly aligned with the claws 27 of the base 13a, as shown in FIG. 9. The contour of the cover 13b is superimposed on the contour of the base 13a in this manner. The ribs 29 are simultaneously aligned with the printed wiring board 22, as shown in FIG. 10. The individual rib 29 contacts with the edge of the printed wiring board 22 at the inclined surface 35 or the contact surface 34, for example. The inclined surface 35 or the contact surface 34 of the rib 29 is guided along the edge of the printed wiring board 22 when the cover 13b is moved toward the base 13a. Since the printed wiring board 22 has a relatively high strength, the printed wiring board 22 can be prevented from damage regardless of the contact of the rib 29.

The cover 13b is being aligned with the base 13a with accuracy while the inclined surface 35 or the contact surface 34 is slid along the printed wiring board 22. When the engagement pieces 28 engage with the claws 27, the cover 13b is coupled with the base 13a. The fingerprint sensor module 19 is positioned in the opening 18. Since the ribs 29 are positioned with a higher accuracy relative to the opening 18 as described above, the sliding movement of the ribs 29 along the printed wiring board 22 enables an accurate alignment of the opening 18 with the fingerprint sensor module 19 on the printed wiring board 22.

The cover 13b is provisionally coupled with the base 13a during the assembling of the display enclosure 13 of the notebook personal computer 11. The ribs 29 of the cover 13b are guided along the edge of the printed wiring board 22 on the base 13a. The cover 13b can be aligned with the base 13a with accuracy before the fingerprint sensor module 19 is located in the opening 18. The edge of the opening 18 is thus reliably prevented from colliding against the fingerprint sensor module 19. This results in a reliable avoidance of damage to the fingerprint sensor module 19.

In addition, the individual rib 29 defines the inclined surface 35 getting farther from the imaginary surface 33 at a position getting farther from the inner surface of the cover 13b. The inclined surfaces 35, 35 of the pair of the ribs 29, 29 are getting farther from each other at positions farther from the inner surface of the cover 13b. Even if there is some difference between the relative positions of the cover 13b and the base 13a, the ribs 29 can slide along the edge of the printed wiring board 22 at the inclined surface 35. The inclined surfaces 35 serve to guide the edge of the printed wiring board 22 to the contact surfaces 34. This results in a smooth assembling of the display enclosure 13.

What is claimed is:

1. An electronic apparatus comprising:
a base;
a cover coupled with the base;
a printed wiring board fixed on the base; and
a rib standing upright from an inner surface of the cover toward the base, the rib defining a contact surface along an imaginary surface surrounding the printed wiring board in an attitude perpendicular to the printed wiring board.

2. The electronic apparatus according to claim 1, wherein the rib defines an inclined surface getting farther from the imaginary surface at a position getting farther from the inner surface of the cover.

3. The electronic apparatus according to claim 1, wherein an opening is formed in the cover at a position corresponding to a position of an electronic component mounted on the printed wiring board.

4. The electronic apparatus according to claim 3, wherein the electronic component is a fingerprint sensor.

5. A method of making an electronic apparatus, comprising coupling a cover to a base with an inner surface of the cover opposed to an inner surface of the base while a rib standing from the inner surface of the cover is guided along a contour of a printed wiring board fixed to the inner surface of the base.

6. The method according to claim 5, wherein the rib defines an inclined surface getting farther from an imaginary surface surrounding the printed wiring board in an attitude perpendicular to the printed wiring board at a position farther from the inner surface of the cover.

7. The method according to claim 5, wherein an opening is formed in the cover at a position corresponding to a position of an electronic component mounted on the printed wiring board.

8. The method according to claim 7, wherein the electronic component is a fingerprint sensor.
